(19) United States
(12) Patent Application Publication
(10) Pub. No.: US 2017/0178980 A1
(43) Pub. Date: Jun. 22, 2017

(54) Full-wafer inspection methods having selectable pixel density

(71) Applicant: Ultratech, Inc., San Jose, CA (US)

(72) Inventors: David M. Owen, Redondo Beach, CA (US); Byoung-Ho Lee, Freemont, CA (US); Eric Bouche, Pleasanton, CA (US); Andrew M. Hawryluk, Los Altos, CA (US)

(73) Assignee: Ultratech, Inc., San Jose, CA (US)

(21) Appl. No.: 15/364,309

(22) Filed: Nov. 30, 2016

Related U.S. Application Data
(60) Provisional application No. 62/269,301, filed on Dec. 18, 2015.

(51) Int. Cl. H01L 21/66; G01B 11/24; G01B 11/30; G01N 21/95; G01N 21/88

(52) U.S. Cl. CPC H01L 22/24; G01N 21/9501; G01N 21/8806; G01B 11/303; G01B 11/2441

(57) ABSTRACT

Full-wafer inspection methods for a semiconductor wafer are disclosed. One method includes making a measurement of a select measurement parameter simultaneously over measurement sites of the entire surface of the semiconductor wafer at a maximum measurement-site pixel density ρₘₐₓ to obtain measurement data, wherein the total number of measurement-site pixels obtained at the maximum measurement-site pixel density ρₘₐₓ is between 10⁴ and 10⁸. The method also includes defining a plurality of zones of the surface of the semiconductor wafer, with each of the zones having a measurement-site pixel density ρ, with at least two of the zones having a different sized measurement-site pixel and thus a different measurement-site pixel density ρ. The method also includes processing the measurement data based on the plurality of zones and the corresponding measurement-site pixel densities ρ. The processed measurement data can be used for statistical process control of the process used to form devices on the semiconductor wafer.

### CROSS-REFERENCE TO RELATED APPLICATIONS

This Application claims priority under 35 USC 119(e) to U.S. Provisional Patent Application Ser. No. 62/269,301, filed on Dec. 18, 2015, and which is incorporated by reference herein.

### FIELD

The present disclosure relates generally to semiconductor fabrication and to inspecting the wafers used in semiconductor fabrication, and more particularly relates to methods of full-wafer inspection that have a selectable pixel density.

The entire disclosure of any publication or patent document mentioned herein is incorporated by reference, including U.S. Pat. Nos. 3,829,219 and 5,526,116 and 6,031,611, and the publications by M. P. Rimmer et al., “Evaluation of large aberrations using lateral-shear interferometer having a variable shear,” App. Opt., Vol. 14, No. 1, pp. 142-150, January 1975, and by Schreiber et al., “Lateral shearing interferometer based on two Ronchi phase gratings in series,” App. Opt., Vol. 36, No. 22, pp. 5321-5324, August 1997. The U.S. patent application Ser. No. 15/362,923, entitled “Systems and methods of characterizing process-induced wafer shape for process control using CGS interferometry” is also incorporated by reference herein.

### BACKGROUND ART

The manufacturing of semiconductor devices in the form of integrated circuit (IC) chips requires processing large numbers of semiconductor wafers. The semiconductor wafers are typically made of silicon and typically have a diameter of 300 mm, with plans to use semiconductor wafers with a diameter of 450 mm in the future. The semiconductor wafers have a thickness of slightly less than 1 mm.

The semiconductor wafers are subjected to numerous different processes (e.g., coating, exposure, bake, etch (wet and dry), polishing, annealing, implanting, film deposition, film growth, cleaning etc.) on the way to forming the final IC device structures. In many instances, some of the steps are repeated multiple times. Because of the fine scale of the features that need to be formed (e.g., as small as several nanometers), the fabrication process needs to be carefully monitored. This involves making inspections of the semiconductor wafer between select steps in the process to ensure that the various steps are being properly implemented.

An important aspect of semiconductor device manufacturing is semiconductor wafer throughput, which is the number of semiconductor wafers per unit time (usually, per hour) that can be processed in a semiconductor production line. The semiconductor wafer throughput is an important factor in determining the cost per semiconductor wafer and thus the cost to manufacture each IC device. It is therefore important that the semiconductor wafer inspections be performed as fast as possible so that the impact on semiconductor wafer throughput is minimized. On the other hand, it is important that a sufficient number of measurements of each semiconductor wafer be obtained to ensure that any defects are identified so that the process can be changed and if necessary, the semiconductor wafer removed from the production line.

As the complexity of the semiconductor devices increases, more and more inspection measurements are required to identify potential defects. There is thus a need for semiconductor wafer inspection systems and methods that substantially optimize the amount of inspection data obtained and analyzed while substantially minimizing the time it takes to collect and process the inspection data.

### SUMMARY

An aspect of the disclosure is a method of inspecting a semiconductor wafer having a surface and a diameter D. The method includes: a) making a measurement of a select measurement parameter simultaneously over measurement sites of the entire surface of the semiconductor wafer at a maximum measurement-site pixel density ρₘₐₓ to obtain measurement data, wherein the total number of measurement-site pixels obtained at the maximum measurement-site pixel density ρₘₐₓ is between 10⁴ and 10⁸; b) defining a plurality of zones of the surface of the semiconductor wafer, with each of the zones having a measurement-site pixel density ρ, with at least two of the zones having a different sized measurement-site pixel and thus a different measurement-site pixel density ρ; and c) processing the measurement data based on the plurality of zones and the corresponding measurement-site pixel densities ρ.

Another aspect of the disclosure is the above-described method, wherein the select measurement parameter is selected from the group of parameters consisting of: a surface topography, a surface curvature, a slope, a device yield, a surface displacement and a stress.

Another aspect of the disclosure is the above-described method, wherein at least one of the plurality of zones has a measurement-site pixel density ρ equal to the maximum measurement-site pixel density ρₘₐₓ.

Another aspect of the disclosure is the above-described method, wherein at least one of the plurality of zones is an annular zone with an outer diameter substantially equal to the diameter D of the semiconductor wafer and with an annular width between 0.03 D and 0.2 D.

Another aspect of the disclosure is the above-described method, wherein the annular width is between 0.05 D and 0.15 D.

Another aspect of the disclosure is the above-described method, further comprising defining the plurality of zones using a variation in the measurement parameter over the surface of the semiconductor wafer.

Another aspect of the disclosure is the above-described method, wherein the plurality of zones are defined within a sub-region of the surface of the semiconductor wafer, and wherein the sub-region is repeated over the surface of the semiconductor wafer.

Another aspect of the disclosure is the above-described method, wherein the sub-region represents at least one of a die, a portion of a die and a lithographic field.

Another aspect of the disclosure is the above-described method, wherein the semiconductor wafer includes devices that include defects, and wherein at least one of the defects is manifested by a change in the select measurement parameter that exceeds a tolerance measured relative to a reference value for the select measurement parameter.

Another aspect of the disclosure is the above-described method, further including selecting the plurality of zones and the corresponding measurement-site pixel densities ρ using the measurement data from at least one previously processed semiconductor wafer.

Another aspect of the disclosure is the above-described method, wherein the measurement-site pixel densities ρ are selected such that the total number of measurement-site pixels is reduced to achieve a select reduction in processing time as compared to the number of measurement-site pixels obtained using the maximum measurement-site pixel density ρₘₐₓ.

Another aspect of the disclosure is the above-described method, wherein the processing time is reduced by at least 10%.

Another aspect of the disclosure is the above-described method, wherein the act a) of making the measurement is performed using interferometry.

Another aspect of the disclosure is the above-described method, wherein the interferometry comprises coherent-gradient-sensing interferometry.

Another aspect of the disclosure is a method of inspecting a semiconductor wafer having a surface, a diameter D, and devices formed thereon. The method includes: a) using a coherent-gradient-sensing interferometer, making a measurement of a select measurement parameter simultaneously over measurement sites of the entire surface of the semiconductor wafer at a maximum measurement-site pixel density ρₘₐₓ to obtain measurement data, wherein the total number of measurement-site pixels obtained at the maximum measurement-site pixel density ρₘₐₓ is between 10⁴ and 10⁸; b) using a yield map of performance of the devices formed on the semiconductor wafer, defining a plurality of zones of the surface of the semiconductor wafer, with each of the zones having a measurement-site pixel density ρ, with at least two of the zones having a different sized measurement-site pixel and thus a different measurement-site pixel density ρ; and c) processing the measurement data based on the plurality of zones and the corresponding measurement-site pixel densities ρ.

Another aspect of the disclosure is the above-described method, wherein the devices are formed using a semiconductor process and further including adjusting the semiconductor process using the processed measurement data of act c).

Another aspect of the disclosure is the above-described method, wherein the select measurement parameter is selected from the group of parameters consisting of: a surface topography, a surface curvature, a slope, a device yield, a surface displacement and a stress.

Another aspect of the disclosure is the above-described method, wherein at least one of the plurality of zones has a measurement-site pixel density ρ equal to the maximum measurement-site pixel density ρₘₐₓ and includes a region of the yield map that includes a lowest yield.

Another aspect of the disclosure is the above-described method, wherein at least one of the plurality of zones is an annular zone with an outer diameter substantially equal to the diameter D of the semiconductor wafer and with an annular width between 0.03 D and 0.2 D.

Another aspect of the disclosure is the above-described method, wherein the annular width is between 0.05 D and 0.15 D.

Another aspect of the disclosure is the above-described method, wherein the measurement-site pixel densities ρ are selected such that the total number of measurement-site pixels is reduced to achieve a select reduction in processing time as compared to the number of measurement-site pixels obtained using the maximum measurement-site pixel density ρₘₐₓ.

Another aspect of the disclosure is the above-described method, wherein the processing time is reduced by at least 10%.

Another aspect of the disclosure is the above-described method, wherein the semiconductor wafer includes devices that include defects, and wherein at least one of the defects is manifested by a change in the select measurement parameter that exceeds a tolerance measured relative to a reference value for the select measurement parameter.

Another aspect of the disclosure is the above-described method, wherein the devices include defects, and further including detecting the defects by comparing values of the select measurement parameter relative to a reference value for the select measurement parameter.

Another aspect of the disclosure is a method of inspecting a semiconductor wafer having a surface, a diameter D, and devices formed thereon. The method includes: a) using a yield map of performance of the devices formed on the semiconductor wafer, defining a plurality of zones of the surface of the semiconductor wafer, with each of the zones having measurement sites with measurement-site pixels and a measurement-site pixel density ρ, with at least two of the zones having a different sized measurement-site pixel and thus a different measurement-site pixel density ρ; b) using an interferometer having an image sensor comprising an array of 10⁴ to 10⁸ sensor pixels: i) configuring the array of sensor pixels to match the measurement-site pixel densities ρ, and ii) making a measurement of a select measurement parameter simultaneously over the measurement sites of the entire surface of the semiconductor wafer to obtain measurement data; and c) processing the measurement data based on the plurality of zones and the corresponding measurement-site pixel densities ρ of the different zones.

Another aspect of the disclosure is the above-described method, wherein the devices are formed using a semiconductor process and further including adjusting the semiconductor process using the processed measurement data of act c).

Another aspect of the disclosure is the above-described method, wherein the select measurement parameter is selected from the group of parameters consisting of: a surface topography, a surface curvature, a slope, a device yield, a surface displacement and a stress.

Another aspect of the disclosure is the above-described method, wherein at least one of the plurality of zones has a measurement-site pixel density ρ equal to a maximum measurement-site pixel density ρₘₐₓ and includes a region of the yield map that includes a lowest yield.

Another aspect of the disclosure is the above-described method, wherein at least one of the plurality of zones is an annular zone with an outer diameter substantially equal to the diameter D of the semiconductor wafer and with an annular width between 0.03 D and 0.2 D.

Another aspect of the disclosure is the above-described method, wherein the annular width is between 0.05 D and 0.15 D.

Another aspect of the disclosure is the above-described method, wherein the measurement-site pixel densities are selected such that the total number of measurement-site pixels is reduced to achieve a select reduction in processing time as compared to the number of measurement-site pixels obtained using the maximum measurement-site pixel density ρₘₐₓ.

Another aspect of the disclosure is the above-described method, wherein the processing time is reduced by at least 10%.

Another aspect of the disclosure is the above-described method, wherein the devices include defects, and further including detecting the defects by comparing values of the select measurement parameter relative to a reference value for the select measurement parameter.

Additional features and advantages of the disclosure are set forth in the detailed description that follows, and in part will be readily apparent to those skilled in the art from that description or recognized by practicing the disclosure as described herein, including the detailed description that follows, the claims, and the appended drawings. The claims are incorporated into and constitute part of the detailed description of the disclosure.

It is to be understood that both the foregoing general description and the following detailed description present embodiments of the disclosure and are intended to provide an overview or framework for understanding the nature and character of the disclosure as it is claimed. The accompanying drawings are included to provide a further understanding of the disclosure and are incorporated into and constitute a part of this specification. The drawings illustrate various embodiments of the disclosure and together with the description serve to explain the principles and operations of the disclosure.

### BRIEF DESCRIPTION OF THE DRAWINGS

FIG. 1 is a schematic diagram of an example coherent gradient sensing (CGS) system that is used in an example to carry out full-wafer measurements at a high measurement density to carry out the methods disclosed herein;

FIGS. 2A and 2B are flow diagrams of two example methods of making inspection measurements of a wafer that includes the option of using selecting zones having respective measurement-site densities;

FIG. 3A is a top-down view of an example wafer showing schematically an example array of measurement-site pixels covering the wafer surface;

FIG. 3B is similar to FIG. 3A and shows how the wafer can be divided into different zones that have different wafer-pixel sizes and thus measurement-site pixel densities;

FIG. 4A is similar to FIG. 3A and illustrates an example of how the wafer can be divided up into “virtual die” that cover the wafer;

FIG. 4B is similar to FIG. 4A and shows how two different zones with different measurement-site pixel densities can be defined for the wafer based on the virtual die;

FIG. 4C is similar to FIG. 4B and shows how three different zones with different measurement-site pixel densities can be defined for the wafer based on the virtual die;

FIG. 5A and 5B show example configurations for zones that have different measurement-site pixel densities;

FIG. 6A is a schematic diagram of an example die-sized region of the wafer, wherein the die-sized region includes three different zones with different measurement-site pixel densities;

FIG. 6B shows how the example die-sized region can be replicated over the wafer in carrying out analysis of the full wafer;

FIG. 7A illustrates an example of adaptive zones defined over the wafer surface;

FIG. 7B illustrates an example die-sized region that includes three adaptive zones, and also shows how the die-sized region is replicated over the wafer in a manner similar to FIG. 6B; and

FIG. 8 is a flow diagram of the analysis process used to obtain a wafer topography based X and Y interferogram data obtained from the CGS system of FIG. 1.

Cartesian coordinates are shown in some of the Figures for the sake of reference and are not intended as being limiting as to orientation or configuration.

### DETAILED DESCRIPTION

Reference is now made in detail to the present preferred embodiments of the disclosure, examples of which are illustrated in the accompanying drawings. Whenever possible, the same reference numbers and symbols are used throughout the drawings to refer to the same or like parts. The claims are incorporated into and constitute part of this detailed description

In the discussion below, the terms “high-density measurement” and “high resolution” mean a measurement or resolution of a select parameter that includes greater than 10⁴ measurement-site pixels or greater than 10⁶ measurement-site pixels over a wafer or region of a wafer. In an example, a high-density measurement has between 10⁴ and 10⁸ pixels, with the upper bound in the example representing a practical upper limit on the measurement technology. Higher upper limits may be obtained in the future with improved measurement technology.

The term “pixel density” ρ means the number of pixels per unit area, and generally refers to the number of pixels per unit area at a measurement site (e.g., zone) on the wafer unless otherwise noted. The maximum pixel density is denoted ρₘₐₓ and corresponds to the highest measurement resolution. The term “pixel” as used herein means a measurement-site pixel unless otherwise noted. Likewise, the term “pixel density” refers to a measurement-site pixel density unless otherwise noted.

The term “zone” as used herein means a region or measurement site of the wafer—and in particular on the wafer surface—that has a select pixel density ρ, wherein different zones have different pixel densities ρ, e.g., zone Z1 has pixel density ρ₁ while zone Z2 has pixel density ρ₂.

The term “device” as used herein means a semiconductor structure formed on and/or in the wafer, including partially formed circuits and like structures. Device performance and device yield can be characterized by select device measurements depending on the type of device. Example measurements include leakage current, drive current and memory retention. Thus, the term “device” is not limited to a fully formed integrated circuit apparatus and can include device portions and features formed along the way to fabricating the final device.

Wafer Inspection Measurements to Identify Process Defects

Aspects of the systems and methods disclosed herein involve making initial full-wafer measurements at a high measurement density (i.e., the maximum pixel density ρₘₐₓ), e.g., greater than 10⁴ pixels or greater than 10⁶ pixels (e.g., between 10⁴ and 10⁸ pixels), and then selecting zones Z having select pixel densities ρ≦ρₘₐₓ that substantially optimize the number of measurements of a wafer surface required to detect certain defects while also substantially minimizing processing time. There are a number of different types of wafer inspection systems that can perform high-density measurements, including systems based on reflectometry, scatterometry, electron beam, interferometry, etc.

The wafer measurements made during wafer inspection can include surface topography and/or surface displacement, from which other parameters can be determined, such as surface stress. A particular type of inspection measurement is associated with a corresponding measurement parameter, e.g., a measurement of surface topography has a corresponding parameter H, which is the surface height (relative to say a perfectly flat wafer surface or to a previously measured surface topography) as function of the (x,y) position on the wafer. A measurement of surface displacement has a corresponding parameter S, which is the displacement of the surface as a function of the (x,y) position on the wafer, as compared to an ideal surface location or a previously measured surface locations.

From one or more measurement parameters, one or more process defects can be identified and quantified. For example, a surface topography measurement of an unpatterned film formed on the wafer surface or an underlying structure may show, for certain (x,y) locations, variations in the height parameter H that are beyond a select tolerance, especially when compared to surface topography measurements made of the wafer surface or underlying structure prior to depositing the unpatterned film. The variations in the height parameter H may be due to film thickness variations, for example. Knowledge of the location of process defects can be used to either ameliorate the defect, or to change a subsequent process to compensate for the defect, or to declare the region of the wafer that includes the defect “bad” and so that any IC chips formed in that region are later scrapped.

Full-Wafer Measurements

Wafer inspection systems can either be scanning systems or areal-image systems. In scanning systems, scattered light is generally collected and in areal imaging systems, an image of an area is collected. In die-to-die inspections, the signal (either the scattered light or the areal image) from one die is compared to the same signal from a second (reference) die. If the two signals are the same, then, the die is considered “defect free”. If the signals are different, then the die may have a defect.

Most inspection tools based on either scanning or areal imaging an entire wafer (in a die-by-die sequence) have a throughput issue. The computation time required to inspect an entire wafer is generally too long. Throughput is typically a few wafers per hour and can be as slow as several hours for a single wafer.

A full-wafer inspection system inspects an entire wafer simultaneously and so provides a relatively high measurement throughput as long as the required computation time can be managed. An example of a full-wafer inspection system is based on coherent gradient sensing (CGS), which employs shearing interferometry. An example CGS inspection system is described in greater detail below.

Briefly, in a CGS inspection system, an interferometric image of the wafer surface is taken and processed (analyzed) to determine the surface topography. The resolution of a CGS inspection system is determined by the sampling frequency (i.e., pixel density ρ) at the wafer surface, which determines the number of pixels that need to be analyzed. Better (higher) resolution leads directly to a larger number of pixels. However, more pixels also lead to more computation and thus lower throughput. An aspect of the methods disclosed herein disclosure allows for varying levels of measurement resolution (pixel density ρ) over the wafer to minimize the amount of computation time while providing for an adequate inspection of the wafer surface, which can include a variety of device structures.

The systems and methods disclosed herein recognize that the highest measurement resolution that uses the maximum pixel density ρₘₐₓ is generally required only in select zones of the wafer. Specifically, in some cases, there are zones on the wafer, such as near the edge, where a high or highest resolution is required, while other zones on the same wafer, such as in the center, where a low or lowest resolution is sufficient. Other potential segregations of the wafer based on zones may be made along the edges of die (within the wafer) vs. the center of the die (within the wafer), or within a given exposure field or die on the wafer. In an example, the zones can have irregular shapes and can be defined by the measurement data rather than being pre-defined.

An aspect of the disclosure is a multi-resolution approach to full-wafer inspection, where smaller pixels (and thus a higher pixel density ρ) are used in one or more zones Z where high resolution is required, and larger pixels (and thus a lower pixel density ρ) are used in one or more other zones. With this approach, computation time can be drastically reduced and throughputs in excess of 100's of wafers per hour can be achieved.

Example CGS Full-Wafer Inspection System

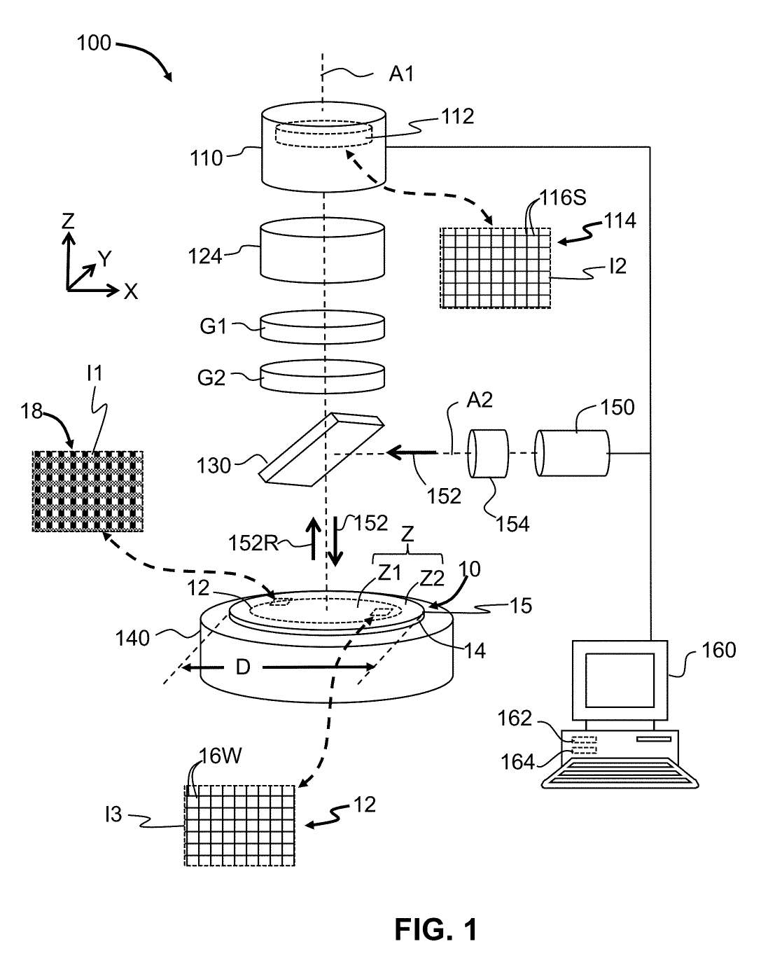

FIG. 1 is a schematic diagram of an example coherent-gradient sensing (CGS) full-wafer inspection system (“CGS system”) 100 that can be used to measure the surface shape (topography) of a wafer 10. The details about how CGS sensing works are described in the above-cited U.S. Pat. No. 6,031,611 (the '611 patent). FIG. 1 herein is based on FIG. 1 of the '611 patent.

The CGS system 100 is based on the principles of lateral shearing interferometry. The CGS system 100 and includes, along an axis A1, a digital camera 110 having an image sensor 112, a filtering lens 124 (e.g., a filter in combination with a lens, as discussed in the '611 patent and shown in FIG. 1 therein), first and second axially spaced-apart diffraction gratings G1 and G2, a beamsplitter 130, and a wafer stage 140. The CGS system 100 also includes a laser 150 arranged along an optical axis A2 that intersects the axis A1 at the beamsplitter 130. A beam expander/collimator 154 is arranged along the optical axis A2 in front of the laser 150.

The CGS system 100 also includes a controller or signal processor 160 operably connected to the digital camera 110 and to the laser 150. An example controller or signal processor 160 is or includes a computer having a processor 162 and a non-transient computer-readable medium (“memory”) 164, which are configured via instructions recorded thereon to control the operation of the CGS system 100 to perform measurements of wafer 10 and carry out the methods described herein.

The wafer 10 has an upper surface (“surface”) 12, a lower or bottom surface 14, an outer edge 15 and a diameter D. The wafer 10 can also include semiconductor features or structures 18 formed on the surface 12, as shown in the close-up inset 11. In an example, an example structure can include a film or stack of films. An example structure can also include patterned features, such as formed using a lithographic process in a lithographic layer, e.g., a dielectric material, or a metal material or a combination of such materials. The surface 12 of wafer 10 can be divided up into two or more zones Z, e.g., Z1, Z2, . . . based on select pixel densities ρ (i.e., ρ₁, ρ₂, . . . , as described below).

With continuing reference to FIG. 1, in operation, the laser 150 and beam expander/collimator 154 form a collimated probe beam 152 that is directed to the upper surface 12 of the wafer 10 by the beamsplitter 130. The collimated probe beam 150 has a diameter of at least the diameter of wafer 10, which can have a diameter of 300 mm for example.

The collimated probe beam 152 reflects from the upper surface 12 of the wafer 10 as a reflected light 152R, which travels upwards through the beamsplitter 130 and through the first and second axially spaced-apart diffraction gratings G1 and G2. The two diffraction gratings G1 and G2 are spaced apart and otherwise configured to shear the reflected light 152R. The reflected light 152R passing through the two diffraction gratings G1 and G2 is then focused onto the image sensor 112 of digital camera 110 using the filtering lens 124.

Because the collimated probe beam 152 illuminates the entire upper surface 12 of the wafer 10 at once, the wafer stage 140 does not need to perform x/y motion to complete the measurement. The reflected light 152R that reflects off of the upper surface 12 of wafer 10 is distorted in accordance with the local height variations (i.e., warpage) of the wafer 10. The interference is generated in a self-referencing manner when the distorted reflected light 152R is steered though the two diffraction gratings G1 and G2. The self-referencing approach eliminates the need for an independent reference beam from, for example, a flat mirror and ensures excellent fringe contrast regardless of the reflectivity of the surface under investigation.

The interference patterns are imaged on to the image sensor 112, which includes an array 114 of sensor pixels 116S (see the inset 12). In an example, the array 114 of sensor pixels 116S is defined by the image sensor 112 such as a CCD having an array 114 of 2048×2048 of sensor pixels 116S (i.e., about 4.2×10⁶ pixels). In an example, the image sensor 112 can be configured (e.g., via programming) to combine pixels or to otherwise perform sensing in groups of pixels. This particular image sensor configuration can be used to collect measurement data at different pixel densities directly rather than capturing the data at the maximum pixel density ρₘₐₓ and then reducing the pixel density via a post-processing step. In an example, the image sensor 112 is part of a digital camera (not shown), which is configured via programmable electronics to define an image capture mode, e.g., maximum pixel density ρₘₐₓ or a reduced pixel density ρ for select regions of the image sensor 112.

The sensor pixels 116S define corresponding measurement-site pixels 16W (see the inset I3), whose size (area) is related to the size (area) of sensor pixels 116S via a magnification factor M defined by the filtering lens 124. The measurement-site pixels 16W have a size that defines the pixel density ρ. As noted above, the size of measurement-site pixels 16W can vary with position on the wafer 10, e.g., as a function of the aforementioned zones Z, so that the corresponding pixel density ρ can also vary with position (zones) on the wafer 10 (i.e., ρ=ρ(x,y)).

The CGS system 100 essentially compares the relative heights of two points on the upper surface 12 of wafer 10 that are separated by a fixed distance w, which is called the shearing distance. Physically, the change in height over a fixed distance provides slope or tilt information, and the fringes in a CGS interference pattern are contours of constant slope. For a given probe wavelength λ and grating pitch ρ for the two diffraction gratings G1 and G2, the shearing distance scales with the distance between the two diffraction gratings G1 and G2. The sensitivity of the interferometer or the slope per fringe is determined by the ratio of the probe wavelength λ to the shearing distance ω.

To reconstruct the shape of the upper surface 12 of the wafer 10 being inspected, interference data in two orthogonal directions must be collected. Collection of the slope data in the x-direction and y-direction is achieved in parallel by two independent grating and camera sets, such as disclosed in the '611 patent. The slope data derived from the interference patterns is integrated numerically to generate the surface shape or topography of wafer 10.

In an example, for each direction, a series of 10 phase-shifted interference patterns are collected at 45-degree increments in phase. The phase shifting is achieved by moving the two diffraction gratings G1 and G2 in the direction parallel to the shearing direction. The phase shifting provides several advantages. For patterned wafer measurement, the most notable advantage is that the fringe contrast can be effectively separated from the pattern contrast, which is static with the phase shifting. The phase shifting, along with the inherent self-referencing nature of the CGS technique, results in relatively high measurement integrity on patterned wafers with widely varying nominal reflectivity. There is no need for dedicated or distinct targets, pads or other specialized features in the layout on the upper surface 12 of wafer 10.

The mapping of a 300 mm wafer 10 onto an image sensor 112 having the aforementioned 2048×2048 sensor array results in each sensor pixel 116S corresponding to a measurement-site pixel 16W having a square area of approximately 150 microns on the upper surface 12 of wafer 10. As a result, a 300 mm upper surface 12 of wafer 10 can be mapped with greater than 3×10⁶ data points with measurement times of just a few seconds. This constitutes a high-density surface shape (topography) measurement.

For increased system throughput, the 2048×2048 CCD array results can be down-sampled, e.g., to a 1024×1024 array, resulting in the measurement-site pixels 16W having an area of approximately 300 microns. This allows for a throughput for the CGS system 100 of greater than 100 wafers per hour (wph). The down-sampled data result in a 300 mm upper surface 12 of wafer 10 being mapped with approximately 800,000 measurement-site pixels 16W. This down-sample data still represents a high-density shape measurement.

Note that for stress-induced wafer bending, the shortest in-plane length scale over which the wafer 10 can deform is twice its thickness. As such, the 300 micron size for measurement-site pixel 16W adequately characterizes deformation of a typical 300 mm wafer 10 whose thickness is 775 microns. A higher resolution with a measurement-site pixel 16W having a size of approximately 150 microns can be used for thinned wafers as required.

The CGS system 100 has advantages for measuring the shape of wafer 10 as compared to traditional interferometers that measure z-height. First, the self-referencing nature of the CGS technique provides high-contrast fringes regardless of the nominal reflectivity of the upper surface 12 of wafer 10 because the two beams that are interfered have similar intensity. Traditional interferometers that rely on a reference surface may lose fringe contrast if the reference beam is significantly brighter than the probe beam due to a low-reflectivity wafer. Second, for typical wafer deformations of tens to hundreds of microns, the CGS fringes have width and spacing much larger than typical pattern features. Such fringe patterns are much more robust for common fringe analysis techniques because the CGS fringes are reasonable smooth and continuous across the entire wafer 10. Traditional interferometers may have fringe patterns that become discontinuous and difficult to resolve in the presence of patterning making fringe analysis challenging if not impossible.

It is noted that wafer shape characterization has historically relied on a relatively low number of (e.g., a few hundred of) point-by-point measurements to generate low-density maps of the wafer geometry. The CGS system 100 enables patterned wafer inspection that can provide an entire wafer map with greater than 5×10⁵ pixels (data points), e.g., up to about 3×10⁶ pixels (data points) per wafer, with a resolution of about 150 microns per pixel. In an example, the number of (initial) data points (pixels) is in the range from 10⁵ to 10⁸, or in another example is in the range from 5×10⁵to 5×10⁶.

The full-wafer CGS interferometer can image precisely the upper surface 12 of the wafer 10 in a few seconds, enabling 100% in-line monitoring of individual wafer shape. Its self-referencing feature allows the inspection to be made on any type of surface or films stack, and does not require a measurement target. This capability can be applied for MEOL and BEOL process monitoring for a variety of applications, including wafer warpage, process induced topography for TSV and other critical steps to control process induced yield issues.

Selectable Pixel Density

An aspect of the methods disclosed herein includes taking the initial high-density wafer measurements based on the maximum pixel density ρₘₐₓ and creating a distribution of select pixel densities ρ over the wafer 10, wherein at least one of the select pixel densities ρ is less than the maximum pixel density ρ_{max.} In an example, at least one of the select pixel densities ρ is equal to the maximum pixel density ρₘₐₓ.

The resolution of an image-based measurement or inspections system is determined by the mapping of the upper surface 12 of wafer 10 under inspection to the image sensor 112. As a result, for a given configuration, a single sensor pixel 116S on the image sensor 112 corresponds to a single measurement-site pixel 16W of a related size on the upper surface 12 of wafer 10, as described above.

The methods disclosed herein recognize that in practice, the local resolution requirements at the upper surface 12 of wafer 10 may vary, which in turn creates a varying data-density requirement. Thus, in an example of the method, the measurement resolution can be defined by the user on a zone-by-zone basis, to provide a higher data density (i.e., smaller pixel size) in critical areas (e.g. where the measured quantity varies rapidly) and a lower data density (i.e., larger pixel size) in less critical areas (e.g., where the measured quantity varies relatively slowly).

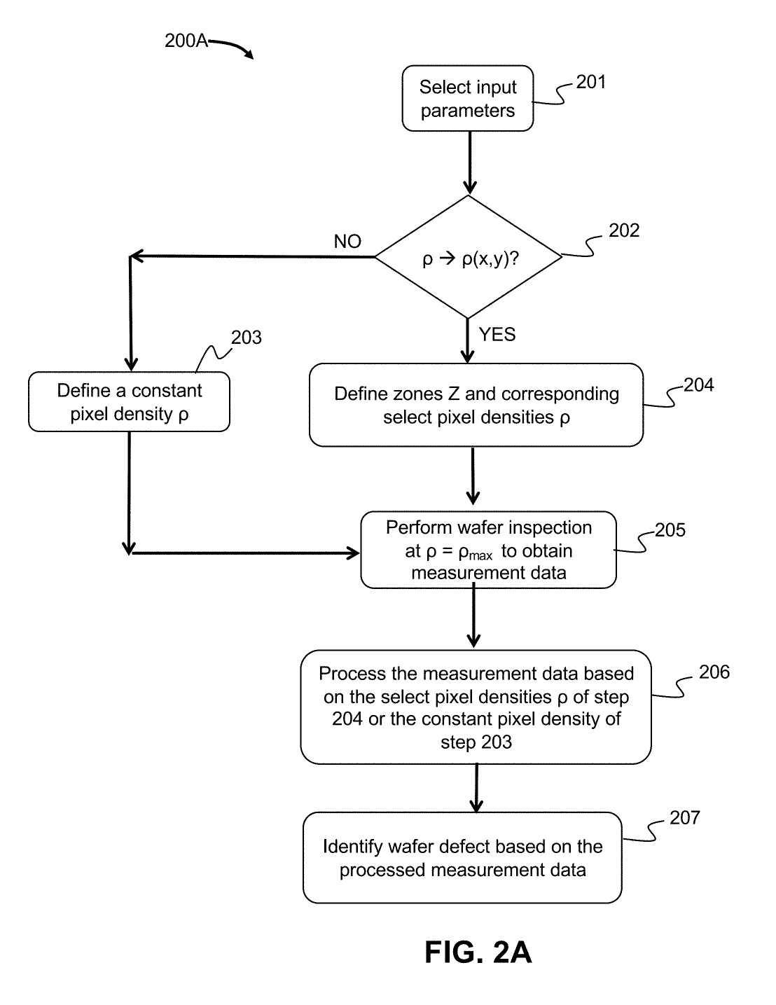

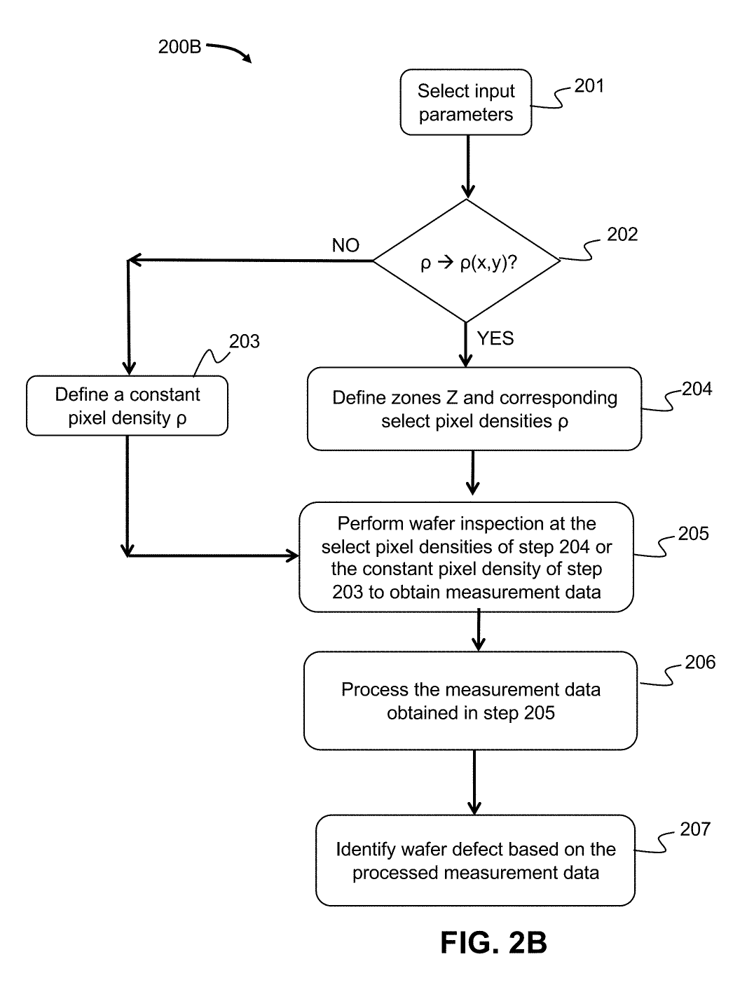

FIG. 2A is a flow diagram 200A that shows the steps of an example wafer inspection method as disclosed herein. The flow diagram 200A includes a step 201 that selects the input parameters to be evaluated by the wafer inspection process. These parameters can include for example the height H(x,y) or surface displacement S(x,y) or orthogonal surface slopes sₓ(x,y) and s_{y}(x,y).

The next step 202 is a query step that asks “ρ→ρ(x,y)?,” i.e., whether a varying pixel density ρ can and should be used. If the answer to the query is “NO,” then the method proceeds to a step 203 of selecting a constant pixel density ρ, i.e., a constant pixel size for the entire wafer 10. If the answer to the query is “YES,” then the method proceeds to a step 204, which involves selecting different pixel densities ρ (i.e., different pixel sizes) for select zones Z on the wafer 10, based on the type of input parameters being considered, the nature of the defects being inspected for, and so on. The method then proceeds to a step 205 of performing the wafer inspection to collect the measurement data. As noted above, in one case the measurement data is collected at the maximum pixel density ρ=ρₘₐₓ. In another case discussed below in connection with the flow diagram 200B of FIG. 2B, the measurement data can be collected in the step 205 using the select pixel densities ρ.

The method then moves to a step 206 of processing the measurement data according to the selected pixel densities ρ of the step 204 or the constant pixel density ρ of the step 203. The method then proceeds to a step 207 of identifying at least one wafer defect based on the processed measurement data of the step 206.

FIG. 2B is a flow diagram 200B similar to the flow diagram 200A of FIG. 2A and illustrates on example where the step 205 performs the wafer inspection at the select pixel densities ρ rather than at the maximum pixel density ρₘₐₓ. In this case, the step 206 already includes the measurement data with different pixel densities ρ as a function of position on the wafer 10, i.e., in select zones Z.

The different user-defined zones for different pixel densities ρ are usually determined by one of two methods: regions of greatest variation in a wafer shape metric of interest (e.g. local flatness, in-plane displacement) and regions of poorest device yields or other performance metric. Upon initial inspection of the wafers 10, the user can identify regions of greatest curvature (representing areas on the wafer 10 where the surface topography has the greatest slope, or change per unit distance). These regions will have the greatest mechanical stresses in the wafer 10 and will typically distort the in-plane surface of the wafer 10. These stresses can also impact the device performance. The device yield is often the best metric to determine which areas are to be inspected at high resolution. Areas that are yielding well do not need improvements, however, areas that have poor device yields need further inspection and improvement. With a yield map, the user can identify which areas are to be inspected at higher resolution. Often, these regions are near the outer edges 15 of the wafer 10 (where typical process equipment is less uniform) or near the boundaries of device “blocks” (i.e., the intersection of memory and logic blocks on a device). In the absence of device yield data, the user can select regions along the edges 15 of the wafer 10 and the regions at the intersection of device blocks. However, once device yield data is obtained, the user may modify the locations of the various zones. The zones Z may also be determined adaptively. In the adaptive case, the user may define a threshold for a value describing the local variability or absolute value of a parameter of interest (e.g. local flatness or in-plane displacement). During analysis of the data, the threshold will be compared to the analyzed data and if the threshold is exceeded, the local density of data can be increased. In the increase in density can be incremental or determined based on the local value relative to the threshold. For example, the data may be analysed initially at a density 4× below the maximum density and a metric such as in-plane displacement can be evaluated based on the low-data-density result. If the local displacement is greater than a critical threshold (e.g. 10 nm) then the data density can be increased in those regions. The criteria associated with adaptively increasing the data density may take many forms, but all will have the underlying concept of requiring that a specific data density is needed to characterize a particular level of a critical metric (e.g. in-plane displacement above 10 nm).

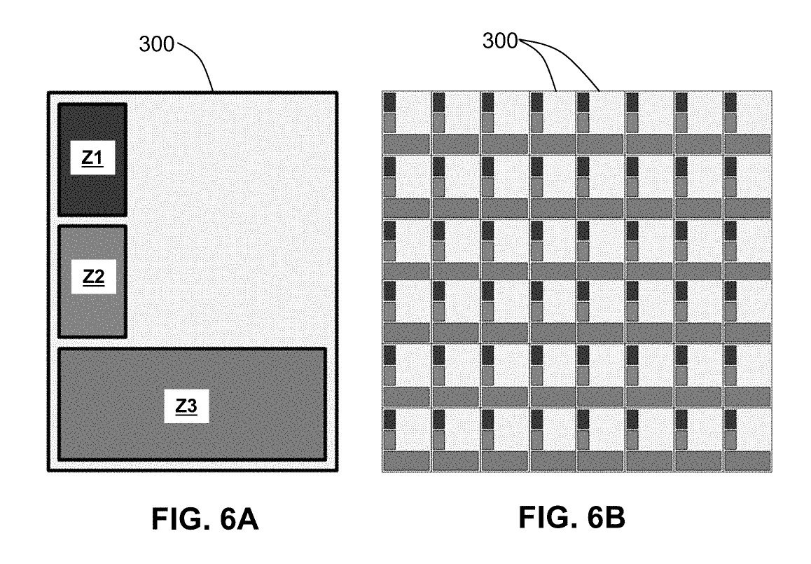

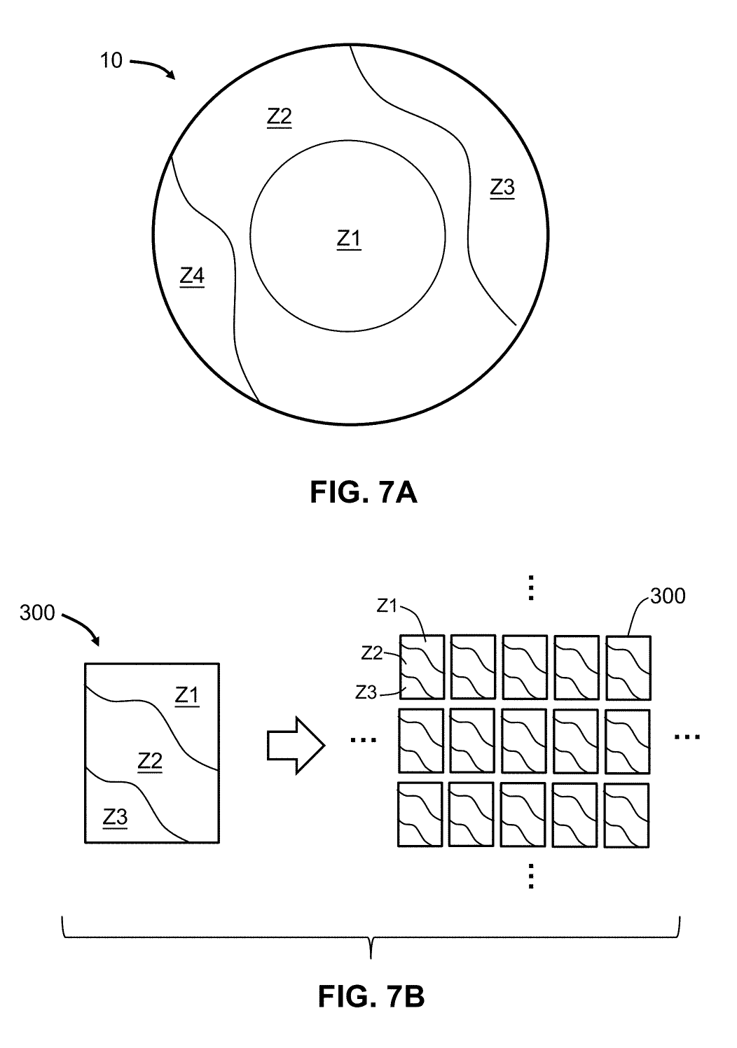

A special case of this approach involves one or more repeating zones Z, such as a associated rectangle corresponding to single device or lithographic field, wherein the varying resolution is specified within one or more zones Z of the rectangle and then repeated over the upper surface 12 of wafer 10. An example of such a case is discussed in greater detail below in connection with FIGS. 6A, 6B and 7A, 7B.

The time required for analysis of the inspection measurement data is generally proportional to the number of measurement-site pixels 16W involved in the full-wafer measurement. Using the conventional approach of uniform resolution or a single size for measurement-site pixel 16W for the entire wafer 10, a doubling of the measurement resolution in certain areas of the wafer 10 will then require that the number of pixels in the entire field to quadruple—resulting in a 4× increase in computation time. However, if the resolution is improved only in selected zones Z (such as along an annular zone adjacent the edge 15 of wafer 10), the increase of the computation time is much more modest as compared to having the maximum measurement resolution for the entire wafer 10.

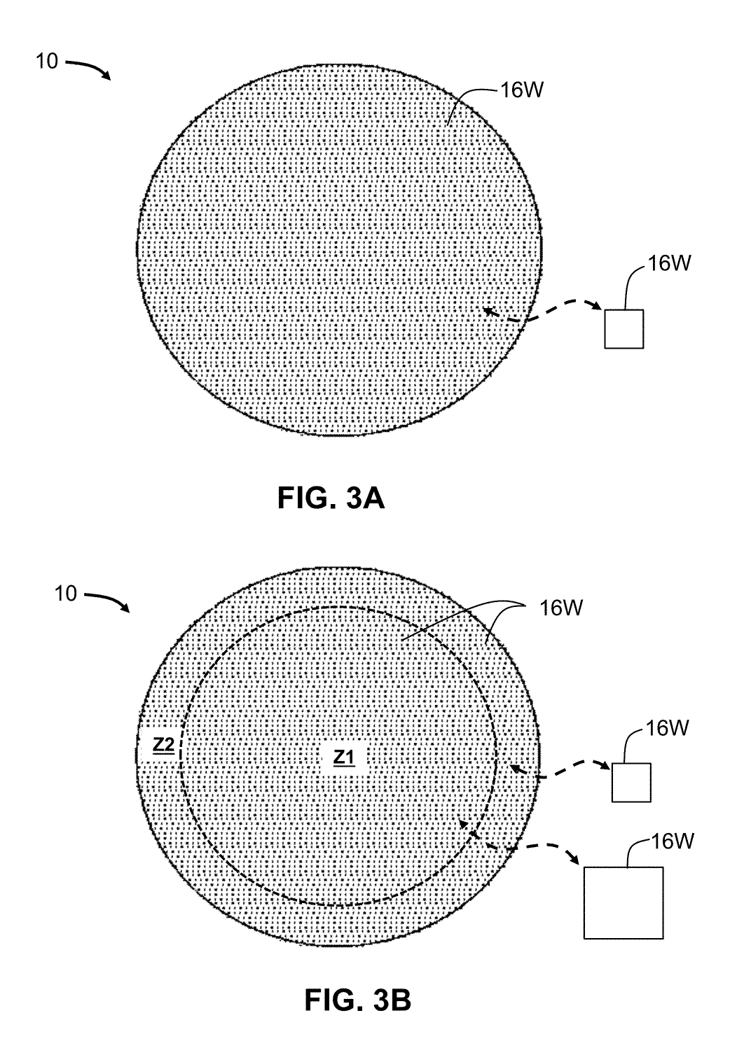

FIG. 3A is a schematic top-down view of an example 300-mm wafer 10 with measurement-site pixels 16W. For the sake of example, consider that each measurement-site pixel 16W has dimensions of 300×300 microns, for a total of 785,397 measurement-site pixels. To increase the resolution by 2× everywhere (i.e., the measurement-site pixel area is decreased to 150×150 microns), the number of pixels quadruple to 3,141,590, resulting in a 4× increase in computation time per wafer.

Consider now the case illustrated in FIG. 3B, where the higher resolution for the measurement-site pixels 16W is only required in an annular zone Z2 at the outer 25 mm of this wafer 10 while the 300×300 micron measurement-site pixels 16W are used in a zone Z1 of radius 250 mm from the center of the wafer 10. The two zones Z1 and Z2 are delineated by the dashed-line circle in FIG. 3B and these two zones Z1 and Z2 have respective pixel densities of ρ₁ and ρ₂, where ρ₁=4ρ₂. For this example configuration, the total number of measurement-site pixels 16W is now only 1,505,339, or approximately half that of using the smaller fixed-size pixel everywhere. This leads directly to higher throughput (i.e., about 2× higher, or a 50% reduction in processing time) as compared to the uniform pixel density case of FIG. 3A.

In an example, the measurement-site densities ρ are selected such that the total number of measurement-site pixels 16W is reduced to achieve a select processing time or acquisition time. In an example, wherein the measurement-site densities ρ are selected such that the total number of measurement-site pixels 16W is reduced by at least 10% as compared to the number of measurement-site pixels 16W obtained using the maximum measurement-site pixel density ρₘₐₓ. In another example, the measurement-site densities p are selected such that the total number of measurement-site pixels 16W is reduced by at least 20% as compared to the number of measurement-site pixels 16W obtained using the maximum measurement-site pixel density ρₘₐₓ. In another example, the measurement-site densities ρ are selected such that the total number of measurement-site pixels 16W is reduced by at least 50% as compared to the number of measurement-site pixels 16W obtained using the maximum measurement-site pixel density ρₘₐₓ.

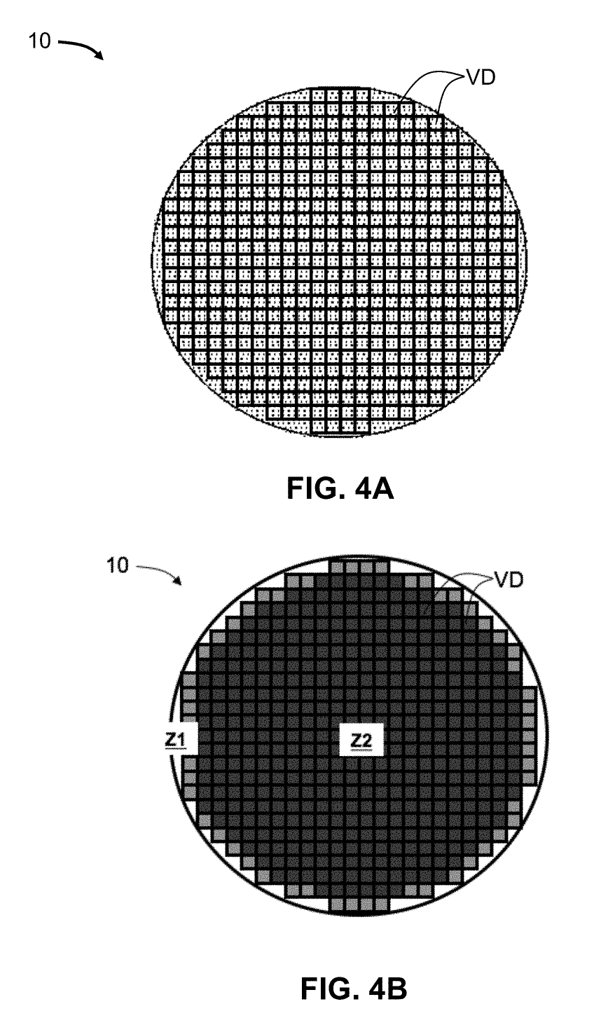

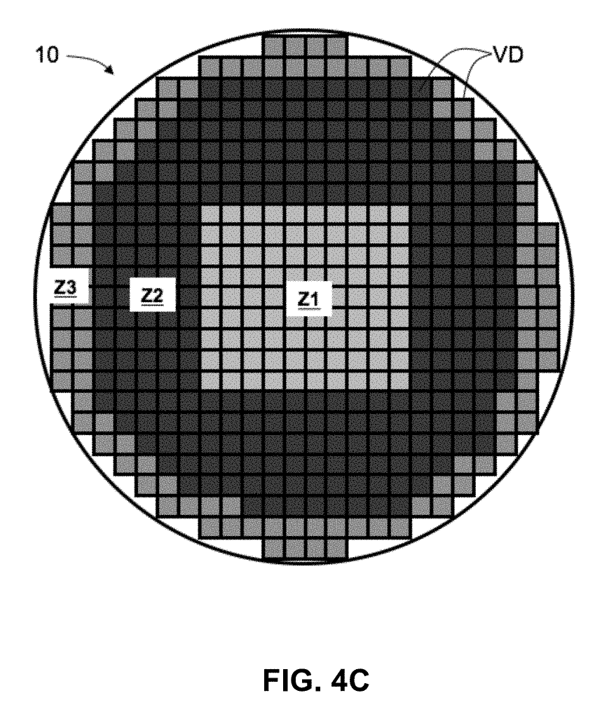

FIG. 4A is similar to FIG. 3A and illustrates an example of where the wafer 10 is divided up into virtual dies VD each containing multiple measurement-site pixels 16W. The example virtual dies VD of FIG. 4A are shown as squares more generally can be rectangular. FIG. 4B is similar to FIG. 4A and shows how the virtual dies VD can be used to define multiple zones Z, e.g., two zones Z1 and Z2, with the two zones Z1 and Z2 having different sized measurement-site pixels 16W (and thus different pixel densities ρ₁ and ρ₂), such as shown in FIG. 3B.

FIG. 4C shows an example where the virtual dies VD are highlighted as green, red and blue to define respective zones Z1, Z2 and Z3 having different measurement resolutions and hence different pixel densities ρ₁, ρ₂ and ρ₃.

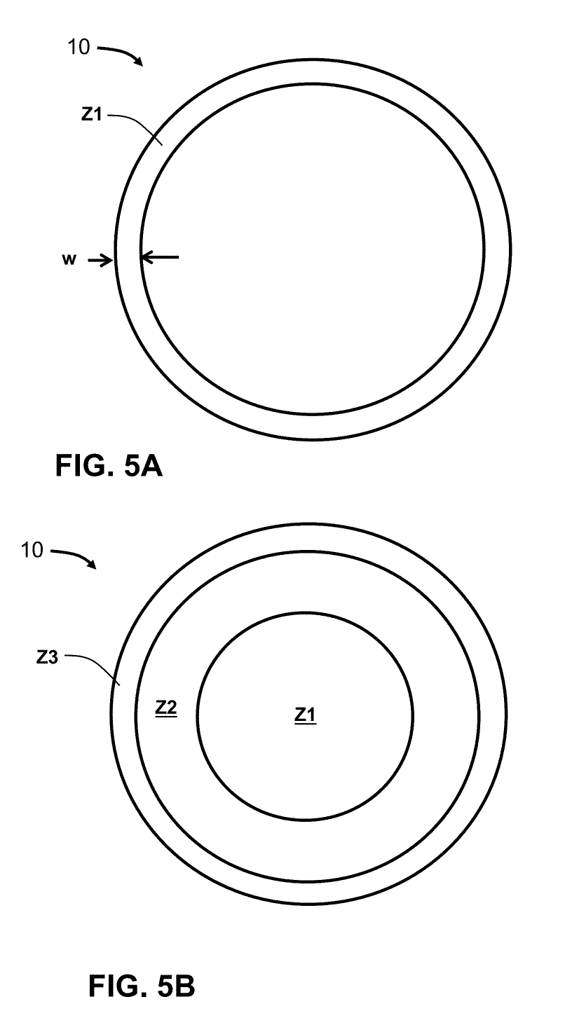

The zones Z can be specified to have an arbitrary shape, independent of the features of the individual devices. FIGS. 5A and 5B show examples of annular and circular zones Z. The simple annular zone Z1 of FIG. 5A can have for example a 20 mm annular width w, with an outer diameter that matches the wafer diameter D. FIG. 5B shows concentric zones Z1, Z2 and Z3, wherein the inner zone Z1 has diameter in the range from 80 mm to 150 mm, the middle zone Z2 has an annular width of 20 mm to 80 mm, and the outer zone Z3 has an annular width w of 15 to 30 mm, with the outer diameter being the same as the wafer diameter D. In one example, the annular width w of the outer zone Z3 is between 0.03 D and 0.2 D, while in another example is between 0.05 D and 0.15 D.

More complex arrangement for zones Z having different pixel densities ρ can be implemented. FIG. 6A is a schematic representation of a rectangular individual die 300 on the wafer 10. Within the individual die 300, there are three zones Z1, Z2 and Z3 that require varying data density, i.e., different sizes for measurement-site pixels 16W. Once the zones Z are defined for a single die, the die pattern can be replicated for the other dies and thus across the whole wafer 10. FIG. 6B shows the replication of the die pattern (or “die resolution map”) based on FIG. 6A for forty-eight die 300 (6 rows by 8 columns). A typical wafer 10 will have hundreds of die 300. The die 300 represents an example of a sub-region of the upper surface 12 of wafer 10. Another example sub-region is a lithographic field, which in an example can contain multiple die. Another example sub-region is within the die 300. Thus, the sub-regions can have a variety of sizes and shapes, and in an example can be defined by the lithographic process and the structures being formed thereby, as well as by the methods used to pattern the wafer 10.

In an example, zones Z are defined based on an adaptive approach based on how rapidly the measurement data is changes as a function of position on the wafer 10. Such zones Z can be referred to as “adaptive zones.” Thus, the data can be used to define adaptive zones Z, as opposed to a user pre-defining the zones Z. In an example, the adaptive zones Z can be defined within a die, such as die 300 shown in FIG. 6A.

FIG. 7A is a top-down view of an example wafer 10 that shows examples of adaptive zones Z1, Z2, Z3 and Z4 that have irregular shapes due to a non-uniform variation in the measurement parameter. In the example, there are four adaptive zones, Z1 through Z4. The data indicate that zone Z1 can have the lowest pixel density ρ₁, zone Z3 and Z4 have the highest pixel densities ρ₃=ρ₄=ρₘₐₓ, and that zone Z2 can have an intermediate pixel density ρ₁<ρ₂<ρₘₐₓ. In an example, the particular pixel density (resolution) for a given adaptive zone Z is defined by performing a spectral analysis (e.g., Fourier analysis) of the data and determining a suitable sampling frequency for the frequency of variation of the measurement parameter for the given zone Z.

FIG. 7B shows a close-up view of an example wafer sub-region in the form of die 300 that includes three adapted zones Z1, Z2 and Z3 that have respective pixel densities ρ₁, ρ₂ and ρ₃. In an example, zone Z2 has the lowest pixel density ρ₂ and zones Z1 and Z3 require either the highest pixel density, ρ₁=ρ₂=ρₘₐₓ, or pixel densities that are at least higher than ρ₁, i.e., ρ₁<ρ₂, ρ₃. FIG. 7B also shows how the example die 300 is replicated to fill the upper surface 12 of wafer 10 in the same manner shown in FIG. 6B.

There are a number of other approaches for defining the pixel density (resolution) For example, to obtain coarser resolution, one can simply sample “every N^{th} pixel” or average N² pixels together—for example, sample every other pixel, or average 2-“x” pixels and 2-“y” pixels. This has the impact of reducing the spatial resolution by N and reducing the information density by N².

To obtain a finer spatial resolution, one can interpolate data in between pixels. This is particularly attractive with a CGS system 100, where the phase front between the two beams is “sheared” by a fraction of a wavelength. Typically, 4 to 16 different measurements are made with different phase shifts. With this information, one can interpolate the information at a spatial dimension that is smaller than the pixel size. As a result, the CGS system 100 is particularly well suited for the task of defining zones of different pixel density ρ. In an example, the pixel density ρ is defined in different zones Z by averaging pixels together to obtain coarser resolution in one zone and to interpolate between pixels to obtain finer resolution in another zone.

To achieve the desired variation in data density in the final inspection measurement result, in one example the full data array is sub-sampled at an appropriate step in the data acquisition or data analysis process step (the step 206 of flow diagram 200A of FIG. 2A) since the initial full-wafer measurement is at the maximum pixel density ρₘₐₓ. The decision regarding where to implement the sub-sampling process includes several factors, including minimizing the total acquisition and analysis time, the complexity of the implementation and the integrity of the final result.

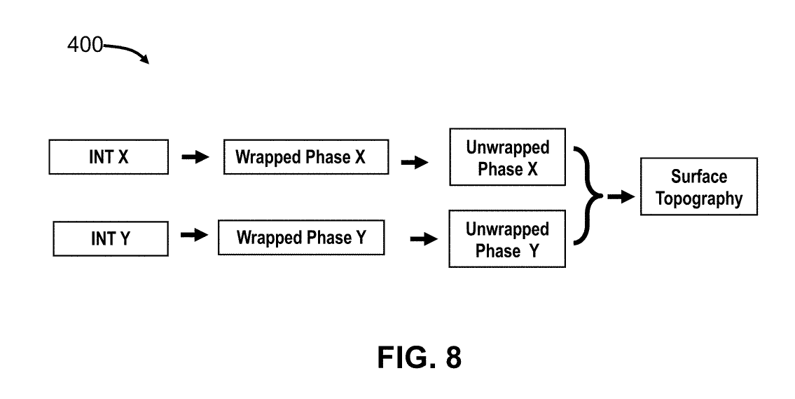

FIG. 8 is a flow diagram 400 of the general analysis steps used for processing data from the CGS system 100. The analysis generates (X,Y) interferometric data “INT X” and “INT Y” using shear in two orthogonal directions. In this process flow, each subsequent step requires the application of algorithms and filters to arrive at the x-direction and y-direction wrapped and unwrapped phases and then the surface topography. These different computations can require dramatically different times. Therefore, one optimization may involve implementation of the sub-sampling at the first rate-limiting analysis step.

Regardless of where the sub-sampling occurs, compatibility across the boundaries between zones Z is necessary to avoid processing errors that could lead to false indications of defects. For example, if any of the zones Z overlap, matching the overlapping portions of the zones is required.

Another second sub-sampling method involves performing the data processing on a non-regular grid. In this implementation, the algorithms may have to be significantly more complex to account for the lack of uniformity in the data distribution.

Other sub-sampling methods can use either: a) only actual pixel locations as data output, or b) a combination of pixels to represent a single location. In another example, the sub-sampling method can use an interpolation algorithm to interpolate the data on to any arbitrary (x,y) coordinate space. The interpolation can also incorporate quality metrics or weighting factors such that the sub-sampling process gives higher weight to higher quality data.

Statistical Process Control and Defect Detection

Wafer defects are typically identified by device performance. There are a multitude of device performance criteria and these criteria change with the device architecture. For example, power devices will have different criteria than memory devices. However, for all devices, there is a stated device performance requirement (such as leakage current, drive current, memory retention, etc.). It is these device performance criteria that determine device yields.

Device yields are typically determined by statistics using a large number of product wafers and by forming what is called a yield map, which relates areas of a (representative) product wafer to device yield.

Once a yield map is generated for the given process, the yield map can be consulted to identify which regions on the wafer 10 have high yield, intermediate yield and low yield. The user can then use this information to designate corresponding zones Z. For example, the user can designate high-resolution zones Z_{H} for the low-yielding wafer regions, and can designate intermediate-resolution zones Z_{I} for the intermediate-yielding wafer regions, and can designate low-resolution zones Z_{L} for the high-yielding wafer regions. In this respect, the map of yield or device-performance data acts as a feedback mechanism to the measurement and inspection process, and may be updated continually, depending on the stability of the process (e.g., depending on the changing features of the yield maps).

It is noted that surface topography information typically implies a probability of an outcome, such as device yield. So for example, if the surface topography measurements result in a measurement of stress of 100 MPa or greater, the yield may be for example 90%. On the other hand, if the resulting stress increases to 200 MPa or greater, the yield may drop to say 80%. Thus, one can identify the relative values (e.g. stress or surface shape) as a function of zone Z to “classify” measurement data by region (e.g. low, medium, high stress).

Thus, rather than detecting defects directly, an aspect of the disclosure is directed to statistical process control based on yield data (e.g., a yield map). The yield data and the surface measurement data (e.g., surface topography measurements) can then be used to control the process to improve (e.g., maximize) device yield, i.e., improve the yield map. Select types of defects for a given process can then be determined based on the knowledge of process statistics, measurements of the device performance parameters, and the known failure mechanisms for the given devices being fabricated.

Example Wafer Inspection Method Steps

Based on the above, an example method of performing inspection of wafer 10 using different pixel densities ρ includes the following steps.

1. User Enables Varying Resolution Inspection
a) User defines select zones Z and a corresponding resolution (pixel density ρ) for each zone; each zone can have different analysis parameters, methods or algorithms specified.
b) User defines metrics for adaptive selection of zones or pixel density related to the variation of the measurement parameter within the area of the wafer 10 that is under inspection.

2. Data Gathering by Detector
a) In one implementation, the image acquisition is completed at maximum resolution (maximum pixel density ρₘₐₓ) and the data resolution is reduced per the user specification during the analysis process. This example process is shown in the flow diagram 200A of FIG. 2A.
b) In an alternate embodiment, the image acquisition is programmed by region or by zones Z such that the resolution of the raw image data corresponds to the select pixel densities ρ, as illustrated in the example process of flow diagram 200B of FIG. 2B.

3. Analyze Data by Zone and Pixel Density

The analysis process may have multiple analysis steps and there may be different algorithms or methods available to complete each analysis step. The sub-sampling of the maximum resolution data into regions of varying resolution (pixel density ρ) can be done at any point in the analysis flow.
a) Analysis steps are completed on each zone independently. For example, if the user specifies 5 different zones Z, in this implementation there would be 5 separate data analyses with a method to enforce compatibility or continuity of the data across the zone boundaries.
b) Analysis steps are completed on the full data set at once with algorithms/calculations modified to operate on sparse data sets (i.e. data distribution is not regular).
c) Options for handling data between zone boundaries can be selected (e.g. overlapping zones, boundary data can be associated with zone of higher or lower resolution).
d) If it is needed, different algorithms can be applied by zone and pixel density.
e) Calculation can be done using a different engine for better throughput.
f) Sub-sampling to obtain the desired resolution for each zone Z can be completed using a weighted or smart sub-sampling, such that the combination of data from multiple pixels can be weighted toward higher-quality data if an appropriate quality metric is available. For the phase-shifted interference patterns, there are several possible quality metrics, such as modulation (i.e. fringe contrast), phase residues, phase-derivative variance.

4. Output Data by Zone
a) Provide data set by user defined
   i. Die level
   ii. Zone level
   iii. Any user defined level

It will be apparent to those skilled in the art that various modifications and variations can be made to the present disclosure without departing from the spirit and scope of the disclosure. Thus it is intended that the present disclosure cover the modifications and variations of this disclosure provided they fall within the scope of the appended claims and their equivalents.

What is claimed is:

1. A method of inspecting a semiconductor wafer having a surface and a diameter D, comprising:
a) making a measurement of a select measurement parameter simultaneously over measurement sites of the entire surface of the semiconductor wafer at a maximum measurement-site pixel density ρₘₐₓ to obtain measurement data, wherein the total number of measurement-site pixels obtained at the maximum measurement-site pixel density ρₘₐₓ is between 10⁴ and 10⁸;
b) defining a plurality of zones of the surface of the semiconductor wafer, with each of the zones having a measurement-site pixel density ρ, with at least two of the zones having a different sized measurement-site pixel and thus a different measurement-site pixel density ρ; and
c) processing the measurement data based on the plurality of zones and the corresponding measurement-site pixel densities ρ.

2. The method according to claim 1, wherein the select measurement parameter is selected from the group of parameters consisting of: a surface topography, a surface curvature, a slope, a device yield, a surface displacement and a stress.

3. The method according to claim 1, wherein at least one of the plurality of zones has a measurement-site pixel density ρ equal to the maximum measurement-site pixel density ρₘₐₓ.

4. The method according to claim 1, wherein at least one of the plurality of zones is an annular zone with an outer diameter substantially equal to the diameter D of the semiconductor wafer and with an annular width between 0.03 D and 0.2 D.

5. The method according to claim 4, wherein the annular width is between 0.05 D and 0.15 D.

6. The method according to claim 1, further comprising defining the plurality of zones using a variation in the measurement parameter over the surface of the semiconductor wafer.

7. The method according to claim 1, wherein the plurality of zones are defined within a sub-region of the surface of the semiconductor wafer, and wherein the sub-region is repeated over the surface of the semiconductor wafer.

8. The method according to claim 7, wherein the sub-region represents at least one of a die, a portion of a die and a lithographic field.

9. The method according to claim 1, wherein the semiconductor wafer includes devices that include defects, and wherein at least one of the defects is manifested by a change in the select measurement parameter that exceeds a tolerance measured relative to a reference value for the select measurement parameter.

10. The method according to claim 1, further comprising selecting the plurality of zones and the corresponding measurement-site pixel densities ρ using the measurement data from at least one previously processed semiconductor wafer.

11. The method according to claim 1, wherein the measurement-site pixel densities ρ are selected such that the total number of measurement-site pixels is reduced to achieve a select reduction in processing time as compared to the number of measurement-site pixels obtained using the maximum measurement-site pixel density ρₘₐₓ.

12. The method according to claim 11, wherein the processing time is reduced by at least 10%.

13. The method according to claim 1, wherein the act a) of making the measurement is performed using interferometry.

14. The method according to claim 13, wherein the interferometry comprises coherent-gradient-sensing interferometry.

15. A method of inspecting a semiconductor wafer having a surface, a diameter D, and devices formed thereon, comprising:
a) using a coherent-gradient-sensing interferometer, making a measurement of a select measurement parameter simultaneously over measurement sites of the entire surface of the semiconductor wafer at a maximum measurement-site pixel density ρₘₐₓ to obtain measurement data, wherein the total number of measurement-site pixels obtained at the maximum measurement-site pixel density ρₘₐₓ is between 10⁴ and 10⁸;
b) using a yield map of performance of the devices formed on the semiconductor wafer, defining a plurality of zones of the surface of the semiconductor wafer, with each of the zones having a measurement-site pixel density ρ, with at least two of the zones having a different sized measurement-site pixel and thus a different measurement-site pixel density ρ;
c) processing the measurement data based on the plurality of zones and the corresponding measurement-site pixel densities ρ.

16. The method according to claim 15, wherein the devices are formed using a semiconductor process and further comprising adjusting the semiconductor process using the processed measurement data of act c).

17. The method according to claim 15, wherein the select measurement parameter is selected from the group of parameters consisting of: a surface topography, a surface curvature, a slope, a device yield, a surface displacement and a stress.

18. The method according to claim 15, wherein at least one of the plurality of zones has a measurement-site pixel density ρ equal to the maximum measurement-site pixel density ρₘₐₓ and includes a region of the yield map that includes a lowest yield.

19. The method according to claim 15, wherein at least one of the plurality of zones is an annular zone with an outer diameter substantially equal to the diameter D of the semiconductor wafer and with an annular width between 0.03 D and 0.2 D.

20. The method according to claim 19, wherein the annular width is between 0.05 D and 0.15 D.

21. The method according to claim 15, wherein the measurement-site pixel densities ρ are selected such that the total number of measurement-site pixels is reduced to achieve a select reduction in processing time as compared to the number of measurement-site pixels obtained using the maximum measurement-site pixel density ρₘₐₓ.

22. The method according to claim 21, wherein the processing time is reduced by at least 10%.

23. The method according to claim 15, wherein the semiconductor wafer includes devices that include defects, and wherein at least one of the defects is manifested by a change in the select measurement parameter that exceeds a tolerance measured relative to a reference value for the select measurement parameter.

24. The method according to claim 23, wherein the devices include defects, and further comprising detecting the defects by comparing values of the select measurement parameter relative to a reference value for the select measurement parameter.

25. A method of inspecting a semiconductor wafer having a surface, a diameter D, and devices formed thereon, comprising:
a) using a yield map of performance of the devices formed on the semiconductor wafer, defining a plurality of zones of the surface of the semiconductor wafer, with each of the zones having measurement sites with measurement-site pixels and a measurement-site pixel density ρ, with at least two of the zones having a different sized measurement-site pixel and thus a different measurement-site pixel density ρ;
b) using an interferometer having an image sensor comprising an array of 10⁴ to 10⁸ sensor pixels: i) configuring the array of sensor pixels to match the measurement-site pixel densities ρ, and ii) making a measurement of a select measurement parameter simultaneously over the measurement sites of the entire surface of the semiconductor wafer to obtain measurement data; and
c) processing the measurement data based on the plurality of zones and the corresponding measurement-site pixel densities ρ of the different zones.

26. The method according to claim 25, wherein the devices are formed using a semiconductor process and further comprising adjusting the semiconductor process using the processed measurement data of act c).

27. The method according to claim 25, wherein the select measurement parameter is selected from the group of parameters consisting of: a surface topography, a surface curvature, a slope, a device yield, a surface displacement and a stress.

28. The method according to claim 25, wherein at least one of the plurality of zones has a measurement-site pixel density ρ equal to a maximum measurement-site pixel density ρₘₐₓ and includes a region of the yield map that includes a lowest yield.

29. The method according to claim 25, wherein at least one of the plurality of zones is an annular zone with an outer diameter substantially equal to the diameter D of the semiconductor wafer and with an annular width between 0.03 D and 0.2 D.

30. The method according to claim 29, wherein the annular width is between 0.05 D and 0.15 D.

31. The method according to claim 25, wherein the measurement-site pixel densities are selected such that the total number of measurement-site pixels is reduced to achieve a select reduction in processing time as compared to the number of measurement-site pixels obtained using the maximum measurement-site pixel density ρₘₐₓ.

32. The method according to claim 31, wherein the processing time is reduced by at least 10%.

33. The method according to claim 25, wherein the devices include defects, and further comprising detecting the defects by comparing values of the select measurement parameter relative to a reference value for the select measurement parameter.
